(19) United States
(12) Patent Application Publication
(10) Pub. No.: US 2016/0354850 A1
(43) Pub. Date: Dec. 8, 2016

(54) METHOD OF MANUFACTURING GEAR-CUTTING TOOLS

(71) Applicant: Caterpillar Inc., Peoria, IL (US)

(72) Inventors: GABRIEL J. ELLICOTT, Peoria Heights, IL (US); Richard G. Marsh, Lugoff, SC (US); Scott A. Johnston, East Peoria, IL (US)

(73) Assignee: Caterpillar Inc., Peoria, IL (US)

(21) Appl. No.: 14/730,317

(22) Filed: Jun. 4, 2015

(51) Int. Cl. B23F 21/16; C21D 1/06; C23C 16/30; C23C 4/134; C23C 4/131; C23C 18/00; C21D 9/22; C25D 7/00

(52) U.S. Cl. CPC B23F 21/16; C21D 9/22; C21D 1/06; C25D 7/00; C23C 4/134; C23C 4/131; C23C 18/00; C23C 16/30

(57) ABSTRACT

A method of manufacturing a gear-cutting tool is disclosed. The gear-cutting tool includes a base portion and cutter teeth extended from the base portion. Each cutter tooth includes a cutting tip portion. The method initiates with hardening the gear-cutting tool with a first hardening process. Thereafter, coating the cutter teeth with a wear resistant material and then hardening the cutting tip portion of each of the cutter teeth with a second hardening process. In the second hardening process, the heat treat is directed to penetrate through the wear resistant material. This process imparts the heat treatment to the wear resistant material and the cutting tip portion of the cutter teeth of the gear-cutting tool.

### TECHNICAL FIELD

The present disclosure relates generally to a method of manufacturing gear-cutting tools. More specifically, the present disclosure relates to the method of manufacturing a gear-cutting tool with improved wear resistance.

### BACKGROUND

Gear-cutting tools, such as gear hobs, are commonly known to produce gears from gear blanks A gear-cutting tool generally includes a cylindrical base portion and a plurality of cutter teeth extended outwardly from the base portion. In a gear cutting process, the gear-cutting tool rotates in unison with a gear blank to cut gear teeth on the gear blank. Upon rotation of the gear-cutting tool with the gear blank, the cutter teeth of the gear-cutting tool removes material from the gear blank to form gear teeth on the gear blank. However, after a period of time, the cutter teeth of the gear-cutting tool begin to wear, resulting in lower quality parts and lengthened machining times if the gear-cutting tool is not changed. Generally, maximum wear of the cutter teeth occurs at a cutting tip portion of the cutter teeth. This reduces the overall work life of the gear-cutting tool and may lead to operational failures. Therefore, the gear-cutting tool is required to be manufactured with improved wear resistance of the gear-cutting tool.

Conventionally, the gear-cutting tool is manufactured by coating each of the cutter teeth with a wear resistant material. The wear resistant material may be manufactured from a hard metal or ceramic material for example. The wear resistance material protects the cutting tip portion of the cutter teeth by improved wear resistance. However, the wear resistant material is also subject to wear, albeit this wear out period being substantially longer than without the coating of the wear resistance material. These types of coated gear-cutting tools are typically more expensive and must be stripped of the coating, reground, and re-coated once the coating of wear resistance material is worn.

U.S. Pat. No. 2,421,995 discloses a method of making a cutting tool with uniform hardness of successive cutting edges. The cutting tool having hardened teeth is subject to shortened life compared to coated cutting teeth type tools and are expensive.

### SUMMARY OF THE INVENTION

Various aspects of the present disclosure are directed towards a method of manufacturing a gear-cutting tool. The gear-cutting tool includes a base portion and a plurality of cutter teeth extended from the base portion. Each cutter tooth of the plurality of cutter teeth includes a cutting tip portion. The method includes hardening the gear-cutting tool with a first hardening process. Thereafter, the plurality of cutter teeth of the gear-cutting tool are coated with a wear resistant material followed by the cutting tip portion of each of the cutter teeth being hardened by a second hardening process. The second hardening process includes directing the heat treat to penetrate the wear resistant material, to impart the heat treatment to the wear resistant material and the cutting tip portion of the plurality of cutter teeth of the gear-cutting tool.

### BRIEF DESCRIPTION OF THE DRAWINGS

FIG. 1 is a plan perspective view of a gear-cutting tool, in accordance with the concepts of the present disclosure;

FIG. 2 is an end view of the gear-cutting tool of FIG. 1, illustrating the cutter teeth of the gear-cutting tool;

FIG. 3 is an enlarged view of the framed portion of FIG. 2;

FIG. 4 is a diagrammatic view of the gear-cutting tool of FIG. 1 at least partially encased by a gear hardening apparatus; and

FIG. 5 is a flow-chart of a process to improve wear resistance of the gear-cutting tool, in accordance with the concepts of the present disclosure.

### DETAILED DESCRIPTION

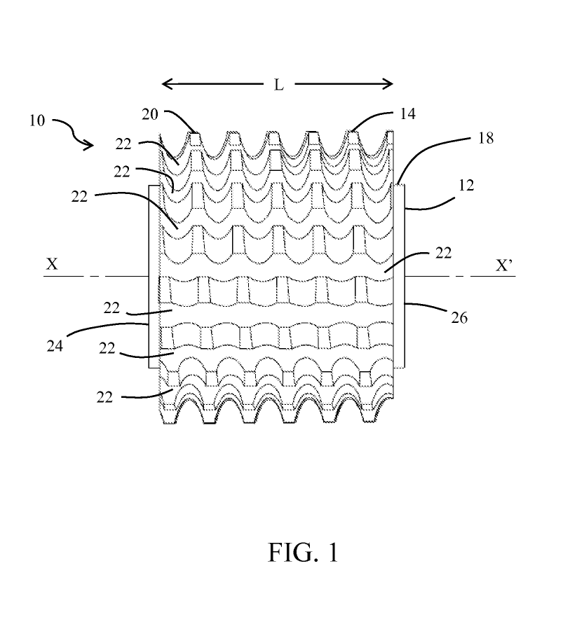

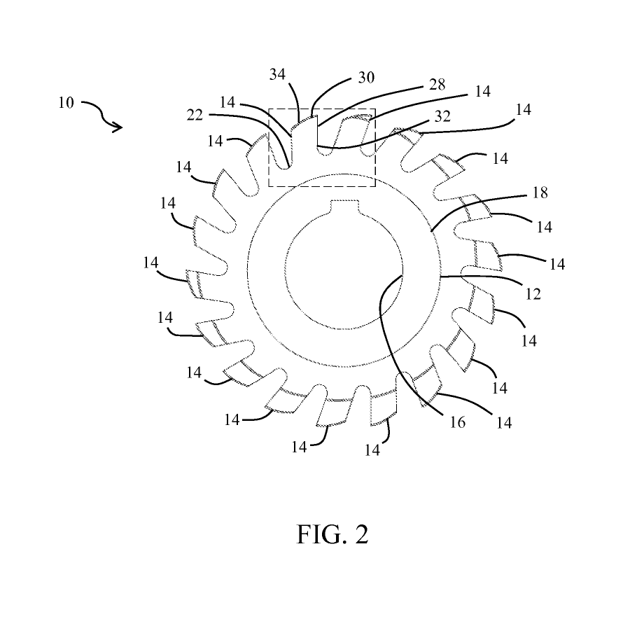

Referring to FIG. 1, there is shown a gear-cutting tool 10, which includes a cylindrical base portion 12 and cutter teeth 14 extending outwardly from the base portion 12. The base portion 12 includes an inner bore 16 (FIG. 2) or shank, an outer periphery 18, and a centerline of the base portion 12 generally extended along a longitudinal axis X-X′. Although this present disclosure contemplates other cutter types which are known to those having ordinary skill, the exemplary embodiment includes a gear hob or gear cutting tool having cutter teeth 14 which are helically arranged relative to the outer periphery 18 of the base portion 12 along the longitudinal axis X-X′. More specifically, the cutter teeth 14 are formed from a raised row 20 intersected with axial grooves 22, to form the cutter teeth 14 between each groove 22. The raised row 20 coils about the outer periphery 18 of the base portion 12 of the gear-cutting tool 10 in a helical manner. The cutter teeth 14 extend radially outward from the base portion 12 and cascade in a helical formation from one end 24 of the gear-cutting tool 10 to the other end 26 of the gear-cutting tool 10.

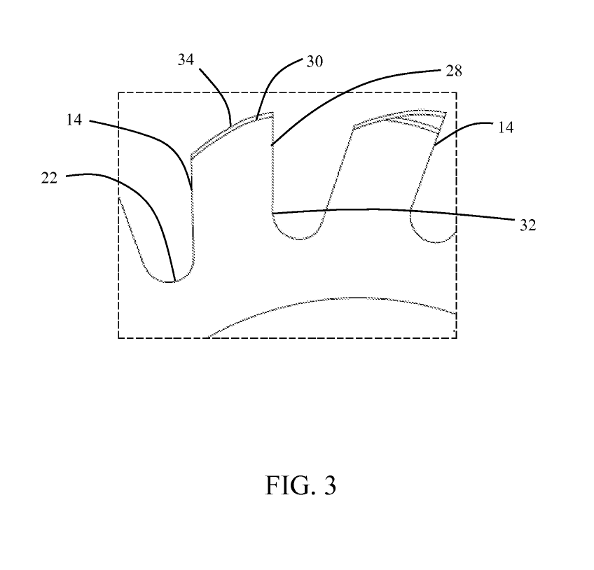

Referring to FIGS. 2 and 3, the cutter teeth 14 are helically arranged on the base portion 12 along the longitudinal axis X-X′, and each groove 22 bisects the raised row 20 to define consecutive cutter teeth 14 separated by the grooves 22 within the gear-cutting tool 10. All grooves 22 extend along a length, L of the gear-cutting tool 10 and are radially and generally equidistantly spaced. The cutter teeth 14 are generally made of a hardened steel material. As best seen in FIG. 3, each cutter tooth 14 has a cutting edge 28 that facilitates the cutting action during a gear cutting process. In addition, each cutter tooth 14 includes a cutting tip portion 30 and an adjacent tooth portion 32. The cutting tip portion 30 is distal relative to the outer periphery 18 of the base portion 12. The adjacent tooth portion 32 is proximal relative to the outer periphery 18 of the base portion 12. Although concepts of the present disclosure are directed towards the gear-cutting tool 10, the present disclosure contemplates that the concepts herein may also be applied to several other tools, such as but not limited to, a gear shaping tool, gear power skiving tool, and a gear-finishing tool.

To manufacture the gear-cutting tool 10 with improved wear resistance, the gear-cutting tool 10 undergoes numerous heat treatment processes. In an exemplary embodiment, a first hardening process is applied to the gear-cutting tool 10. This first hardening process is a general hardening process, in which the gear-cutting tool 10 is heat treated by any of the known heat treatment processes to impart the desired surface and subsurface hardness.

The cutter teeth 14 of the gear-cutting tool 10 are then subjected to a coating of a wear resistant material 34 and forms a substrate for the wear resistant material 34. For ease in reference, the wear resistant material 34 may also be defined as the coating material 34. Several types of coating material 34, may be used, such as, but not limited to, tungsten carbide, chromium oxide, Titanium Nitride, and any other suitable material known to those having ordinary skill in the art. A coating process may include, such as but is not limited to, a twin-arc thermal spray process, a plasma spraying process, vapor deposition, chemical deposition, and/or an electro-plating process.

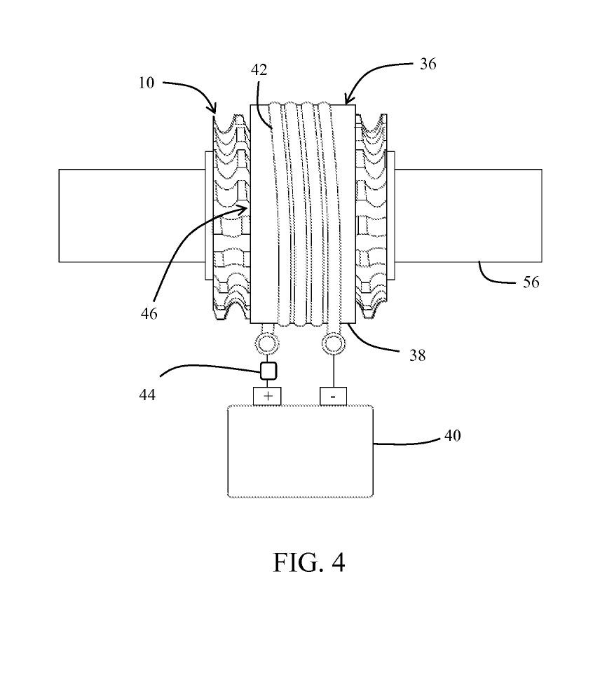

Referring to FIG. 4, there is shown a hardening assembly 36 to perform a second hardening process on the gear-cutting tool 10. The gear-cutting tool is then subjected to hardening with use of the hardening assembly 36. In an embodiment of the present disclosure, the hardening assembly 36 is an induction-hardening element, which may be placed to suitably surround the perimeter of the gear-cutting tool 10 to perform the second hardening process. The hardening assembly 36 includes an induction cylinder 38, a battery unit 40, and an electric coil 42. The electric coil 42 is wound around the induction cylinder 38 and is electrically managed by the battery unit 40, via a control switch 44. Notably, as the control switch 44 is actuated, the electric coil 42 produces alternating magnetic field in an interior 46 of the induction cylinder 38. Although, the present disclosure contemplates the hardening assembly 36 as a thru-feed induction-hardening element, it may be contemplated that the hardening assembly 36 may be a spiral induction-hardening element.

To perform the second hardening process, the gear-cutting tool 10 is positioned in the interior 46 of the induction cylinder 38. In the current embodiment, the electric coil 42 is inductive coil that produces magnetic field in the interior 46 of the induction cylinder 38. As the gear-cutting tool 10 is positioned in the interior 46 of the induction cylinder 38, the magnetic field produced by the electric coil 42 generates eddy current on each of the cutter teeth 14 and corresponding eddy current losses generate heat in the cutting tip portion 30 of each cutter tooth 14 of the gear-cutting tool 10. More specifically, the heat treat of the second hardening process penetrate the coating material 34 and heat both of the coating material 34 and the cutting tip portion 30 of each of the cutter teeth 14 of the gear-cutting tool 10. In an alternate embodiment, the electric coil 42 may be a convection heating coil that transmits heat via convection heating to the cutting tip portion 30 of each cutter tooth 14 of the gear-cutting tool 10. It may be noted that the gear-cutting tool 10 is kept in the induction cylinder 38 until the heat flows through the entire cutting tip portion 30. Before the heat reaches the adjacent tooth portion 32, the gear-cutting tool 10 is removed from the hardening assembly 36 and is quenched in a cold water-bath (or other known quenches to achieve the desired microstructure). This imparts hardness to the cutting tip portion 30 of each cutter teeth 14. As the second hardening process is performed solely on the cutting tip portion 30, the cutting tip portion 30 is imparted with relatively higher hardness relative to the adjacent tooth portion 32.

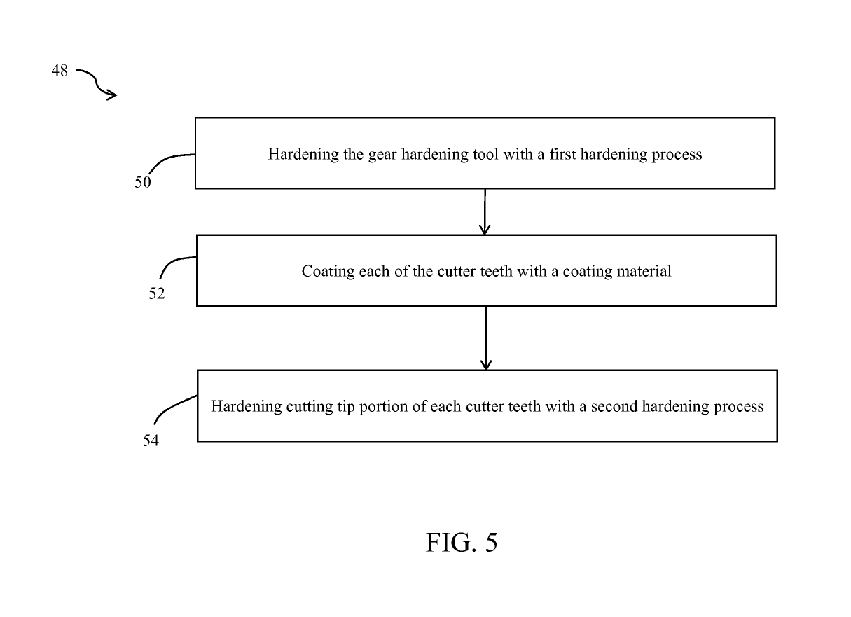

Referring to FIG. 5, there is shown a flow-chart of a method 48 to manufacture the gear-cutting tool 10. The method 48 is discussed in conjunction with each of the FIGS. 1, 2, 3, and 4. The method 48 initiates at step 50.

At step 50, the gear-cutting tool 10 undergoes hardening through first hardening process. In the first hardening process, each of the cutter teeth 14 of the gear-cutting tool 10 is uniformly hardened. More specifically, in this first process, both of the cutting tip portion 30 and the adjacent tooth portion 32 of each of the cutter teeth 14 are hardened. The method 48 then proceeds to step 52.

At step 52, each cutter teeth 14 of the gear-cutting tool 10 is coated with the coating material 34. Therefore, both of the cutting tip portion 30 and the adjacent tooth portion 32 of each of the cutter teeth 14 receive a layer of coating material 34. This further improves wear resistance of the cutter teeth 14. The method 48 then proceeds to step 54.

At step 54, each of the cutter teeth 14 of the gear-cutting tool 10 is hardened by the second hardening process with use of the hardening assembly 36. In the second hardening process, the gear-cutting tool 10 is positioned within the induction cylinder 38 of the hardening assembly 36. When the hardening assembly 36 is actuated, the hardening assembly 36 heats the cutting tip portion 30 of each cutter teeth 14 of the gear-cutting tool 10. Notably, the heat treat of the second hardening process is directed to penetrate through the coating material 34 and heat the cutting tip portion 30 of each of the cutter teeth 14. Thereafter, the gear-cutting tool 10 is quenched in the cold water-bath (or other known method) before the heat reaches the adjacent tooth portion 32. This imparts heat treatment to the coating material 34 and the substrate at the cutting tip portion 30 of each of the cutter teeth 14. In effect, this facilitates improved wear resistance of the gear-cutting tool 10.

### INDUSTRIAL APPLICABILITY

In operation, the gear-cutting tool 10 is manufactured with improved wear resistance by subjecting the gear-cutting tool 10 to a series of heat-treatment processes. More specifically, the gear-cutting tool 10 is manufactured with improved wear resistance by subjecting the gear-cutting tool 10 to hardening by the first hardening process, coating with the coating material 34, and then hardening with the second hardening process.

Initially, the gear-cutting tool 10 is subjected to hardening by the first hardening process. As is already mentioned, in the first hardening process, the gear-cutting tool 10 is heated to a relatively high temperature and then quenched in the cold water-bath (or other known method). This imparts uniform surface hardness and wear resistance to the cutter teeth 14 of the gear-cutting tool 10. More specifically, this improves wear resistance of both of the cutting tip portion 30 and the adjacent tooth portion 32 of each of the cutter teeth 14. Thereafter, the gear-cutting tool 10 is coated with the coating material 34, via the coating process. This further increases the wear resistance of both of the cutting tip portion 30 and the adjacent tooth portion 32 of each of the cutter teeth 14. Thereafter, the gear-cutting tool 10 is subjected to the second hardening process to impart relatively higher hardness to the cutting tip portion 30 than the adjacent tooth portion 32 of each of the cutter teeth 14.

In the second hardening process, the gear-cutting tool 10 is positioned in the interior 46 of the induction cylinder 38 of the hardening assembly 36. For this purpose, a shaft 56 may be attached to the inner bore 16 of the gear-cutting tool 10, which may then be positioned in the interior 46 of the induction cylinder 38, to facilitate the second hardening process. Once the gear-cutting tool 10 is positioned in the interior 46 of the induction cylinder 38 of the hardening assembly 36, the control switch 44 is actuated. Upon actuation of the control switch 44, the electric coil 42 produces a magnetic field in the interior 46 of the induction cylinder 38, which in turn produces heat in the cutting tip portion 30 of each cutter teeth 14 of the gear-cutting tool 10. More specifically, in the second hardening process, the heat treat in the second hardening process is directed to penetrate the coating material 34 and raise the temperature of the cutting tip portion 30. The gear-cutting tool 10 is kept in the interior 46 of the induction cylinder 38 for a period of time, until the cutting tip portion 30 of each cutter teeth 14 is heated. As the cutting tip portion 30 is heated up to a preset temperature, the gear-cutting tool 10 is removed from the induction cylinder 38 of the hardening assembly 36. Next, the gear-cutting tool 10 is quenched in a cold water-bath (or other known method). This process imparts additional hardness to the cutting tip portion 30 relative to the adjacent tooth portion 32. This operation increases overall wear resistance of the gear-cutting tool 10. This results in increased work life of the gear-cutting tool 10.

It should be understood that the above description is intended for illustrative purposes only and is not intended to limit the scope of the present disclosure in any way. Those skilled in the art will appreciate that other aspects of the disclosure may be obtained from a study of the drawings, the disclosure, and the appended claim.

What is claimed is:

1. A method of manufacturing a gear-cutting tool, the gear-cutting tool having a base portion and a plurality of cutter teeth extended from the base portion, each cutter tooth of the plurality of cutter teeth having a cutting tip portion, the method comprising:
hardening the gear-cutting tool with a first hardening process;
coating the plurality of cutter teeth of the gear-cutting tool with a wear resistant material;
hardening the cutting tip portion of each of the plurality of cutter teeth with a second hardening process, wherein the second hardening process including:
directing the heat treat of the second hardening process to penetrate the wear resistant material to impart the heat treatment to the wear resistant material and the cutting tip portion of the plurality of cutter teeth of the gear-cutting tool.
